(19) United States
(12) Patent Application Publication
(10) Pub. No.: US 2025/0212379 A1
(43) Pub. Date: Jun. 26, 2025

(54) STATIC RANDOM ACCESS MEMORY DEVICE

(71) Applicant: IMEC VZW, Leuven (BE)

(72) Inventors: Dawit Burusie Abdi, Leuven (BE); Moritz Brunion, Heverlee (BE)

(21) Appl. No.: 18/982,460

(22) Filed: Dec. 16, 2024

(30) Foreign Application Priority Data
Dec. 22, 2023 (EP) 23219670.9

(51) Int. Cl. H10B 10/00; G11C 11/412; H10D 84/85; H10D 89/10

(52) U.S. Cl. CPC H10B 10/12; G11C 11/412; H10D 89/10; H10D 84/851

(57) ABSTRACT

A static random access memory (SRAM) device includes a plurality of bit cells, each bit-cell including a first half-cell and a second half-cell, each half-cell including a first and a second complementary field-effect transistor (CFET) device. Each CFET device includes a bottom device and a top device stacked on top of the bottom device. The first CFET device includes a common gate shared by the bottom device and the top device and is configured as an inverter cross-coupled to the inverter of the other half-cell. The bottom device of the second CFET device is configured as a first pass-gate for a first port of the half-cell. The top device of the second CFET device is configured as a second pass-gate for a second port of the half-cell.

### CROSS-REFERENCE TO RELATED APPLICATIONS

This application claims foreign priority to European Application No. 23219670.9, filed on Dec. 22, 2023, which is incorporated by reference herein in its entirety.

### BACKGROUND

### Field

The disclosed technology generally relates to a static random access memory (SRAM) device.

### Description of the Related Technology

The demand for higher performance two-port SRAM is increasing especially in advanced system-on-chips (SoCs) include a central processing unit (CPU) and a graphics processing unit (GPU). Parallel processing is the key for these applications, in which the embedded memories with multi-port types are beneficial as they improve system performance by enabling two processors, threads or processes to simultaneously read/write from/to the memories. The 8-transistor (8T) dual-port SRAM bit-cell is able to provide high performance 2 read/write port (2RW) operation. However, such bit-cell can introduce a significant area overhead, typically about 1.5 times larger than the 6T single-port SRAM bit-cell in current technology nodes. Due to the smaller footprint, the 6T single-port bit-cell is generally used in current high-density applications.

### SUMMARY OF CERTAIN INVENTIVE ASPECTS

In view of the above, an object of the disclosed technology is to provide a CFET-based 8T SRAM bit cell suitable for a dual-port implementation, which thus enables approaching the theoretical dual-port to single-port bit-cell footprint ratio of 1.

These objectives are achieved by the solutions of disclosed technology described in the independent claims. Advantageous implementations are described in the dependent claims.

A first aspect of the disclosed technology is a SRAM device, including a plurality of bit cells. Each bit-cell includes a first half-cell and a second half-cell. Each half-cell includes a first and a second CFET devices. Each CFET device includes a bottom device and a top device, where the top device is stacked on top of the bottom device. The first CFET device includes a common gate shared by the bottom device and the top device and is configured as an inverter cross-coupled to the inverter of the other half-cell. The bottom device of the second CFET device is configured as a first pass-gate for a first port of the half-cell and includes a bottom gate coupled to a first word line. The top device of the second CFET device is configured as a second pass-gate for a second port of the half-cell and includes a top gate which is separate from the bottom gate and is coupled to a second word line.

Thus, the disclosed technology is based on the insight that the 8T bit-cell design that is compatible with the CFET device architecture may be realized based on a bit-cell including an equal number of NMOS and PMOS devices. Accordingly, the first pass-gate and the second pass-gate (interchangeably the pass-gate pair) of each half-cell are realized by a CFET device, which means that the first and second pass-gates are complementary devices stacked on top of each other. The bottom device and the top device of the second CFET device (e.g., the first pass-gate and the second pass-gate) may be a PMOS device and an NMOS device, respectively, or vice versa. As the bottom and top gates of the second CFET device are separate, the first pass-gate (the bottom device) and the second pass-gate (the top device) may be individually controlled via the first and second word lines, respectively. Thus, the bit-cell design of the SRAM device according to some aspects is an enabler for a high-density dual port CFET-based SRAM.

In some aspects, each CFET device may include a first and a second source/drain (S/D) region. The common gate of the first CFET device of the first half-cell and the bottom and top gates of the second CFET device of the second half-cell may be arranged along a first gate track, and the common gate of the first CFET device of the second half-cell and the bottom and top gates of the second CFET device of the first half-cell may be arranged along a second gate track, and the first and second gate tracks being parallel to a cell height dimension of the bit-cell.

In some embodiments, each CFET device may include a first and second S/D regions. The S/D regions of the CFET devices of the first half-cell may be arranged along a first active track, and the S/D regions of the CFET devices of the second half-cell may be arranged along a second active track, and the first and second active tracks are parallel to a cell width dimension of the bit-cell and transverse to the cell height dimension.

The two inverters (the first CFET devices) may thus be accommodated along only two parallel gate tracks with a layout such that the inverters are located in a first pair of diagonally opposite quadrants of the bit-cell and the two pass-gate pairs are located in a second pair of diagonally opposite quadrants of the bit-cell. This bit-cell layout facilitates interconnect routing within the bit-cell, for example, the cross-coupling between the inverter pairs since the two cross-couplings between the inverters may be routed within the bit-cell without crossing or blocking each other.

In some embodiments, the first half-cell includes a first common S/D contact arranged between (e.g., and also shared by) the first and second CFET devices of the first half-cell, and the second half-cell includes a second common S/D contact arranged between (e.g., and also shared by) the first and second CFET devices of the second half-cell. Each of the common S/D contact of the first and second half-cell can include a contact extension protruding towards the common S/D contact of the other half-cell (e.g., along the cell-height dimension). The common gates of the first CFET devices of the first and second half-cells can define first and second common gates, respectively. Each of the first and second common gates include a gate extension protruding towards the second CFET device (e.g., towards the bottom and top gates thereof, and along the cell-height dimension) of the other half-cell. In some embodiments, the bit-cell includes a first local cross-coupling interconnect extending between and interconnecting respective tip portions of the gate extension of the first common gate and the contact extension of the second common S/D contact, and a second local cross-coupling interconnect extending between and interconnecting respective tip portions of the gate extension of the second common gate and the contact extension of the first common S/D contact.

These embodiments can further facilitate an area-efficient interconnect routing within the bit-cell since the separation (along the cell-height dimension) between the internal storage nodes defined by the inverter of one half-cell and the common gate of the other half-cell may be bridged at least partly by extending the local S/D contacts and the common gates.

In some embodiments, the tip portion of the gate extension of the first common gate is separated from a tip portion of the bottom and top gates of the second CFET device of the second half-cell by a first gate cut region. In these embodiments, the tip portion of the gate extension of the second common gate is separated from a tip portion of the bottom and top gates of the second CFET device of the first half-cell by a second gate cut region.

Generally described, circuits typically include gate cut regions defined to ensure that a sufficient tip-to-tip separation is provided between gates along a same gate track. Accordingly, by the tip portions of the gate extension and the bottom/top gates along the same gate track being separated by at least a gate cut region, the bit cell layout may provide sufficient process margin with respect to the gate fabrication. The tip portions may, for example, be separated by the gate cut region. This may contribute to a low cell height realization of the bit-cells.

In some embodiments, each of the first and second local cross-coupling interconnects is configured as a first and second metal strap, respectively, extending along the cell width dimension to bridge a distance between the respective tip portions. Thus, the gate extension and contact extension may be interconnected by a simple intra-cell metal strap extending transverse thereto.

The first and second metal straps may, for example, be arranged on top of the respective tip portions.

In some embodiments, the bottom devices are arranged in a bottom device tier of the bit-cell, and the top devices are arranged in a top device tier of the bit-cell. In these embodiments, the gate extension of the first common gate and the contact extension of the second common S/D contact are arranged in the bottom device tier but not the top device tier. In addition, the gate extension of the second common gate and the contact extension of the first common S/D contact are arranged in the top device tier but not the bottom device tier.

Accordingly, the two cross-couplings between the inverters (the first common gate-to-second common S/D contact and the second common gate-to-first common S/D contact) may be split between the bottom and device tier. The first and second metal straps may be offset along the vertical dimension (e.g., the stacking direction of the devices) such that a need for a spacing along the cell height dimension between the metal straps (which accordingly requires a greater cell height dimension) may be mitigated.

In some examples, the gate extension of the first common gate may extend from a bottom gate portion of the first common gate, to protrude relative to a top gate portion of the first common gate. Correspondingly, the contact extension of the second common S/D contact may extend from a bottom contact portion of the second common S/D contact, to protrude relative to a top contact portion of the second common S/D contact. In some cases, the gate extension of the second common gate may extend from a top gate portion of the second common gate, to protrude relative to a bottom gate portion of the second common gate. Correspondingly, the contact extension of the first common S/D contact may extend from a top contact portion of the first common S/D contact to protrude relative to a bottom contact portion of the first common S/D contact.

The first metal strap may be included in a local interconnect layer intermediate the bottom and top device tiers.

The second metal strap may be included in a local interconnect layer arranged on top of the top device tier.

The contact extensions may protrude at least to a midline of bit-cell. Thus, the common gate of either half-cell may only need extend a shorter part of the distance to the second CFET device of the other half-cell to facilitate the cross-coupling, which allows a margin to the bottom and top gates of said second CFET device to be increased.

In some embodiments, each bottom device is a nanosheet-FET device (e.g., including a channel structure formed by a number of nanosheets) and each top device is a Fin Field-effect Transistor (finFET) device including a channel structure (e.g., a fin-shaped channel structure) with a width dimension (e.g., along the cell-height dimension) smaller than a width dimension of a channel structure of each nanosheet-FET device. In some examples, the channel structure of the finFET (e.g., having a narrower channel structure) can further reduce the cell height dimension.

In some embodiments, the bottom devices are arranged in a bottom device tier of the bit cell, and the top devices are arranged in a top device tier of the bit cell,

In these embodiments, the gate extensions of the first and second common gates and the contact extensions of the first and second common S/D contacts are arranged in at least the top device tier.

Accordingly, the two cross-couplings between the inverters (the first common gate-to-second common S/D contact and the second common gate-to-first common S/D contact) may hence be provided by metal straps in a common local interconnect layer arranged on top of the top device tiers. This may reduce a complexity of the interconnect routing within the bit cell.

In some embodiments, the first and second pass-gates of the first half-cell are coupled to a first and second bit line, respectively. The first and second pass-gates of the second half-cell are coupled to a first and second complementary bit line, and the inverters of the first and second half-cells are coupled to a first power rail and second power rail, one providing a pull-up voltage and the other providing a pull-down voltage.

In these embodiments, the two inverters (the first CFET devices) are accommodated along two parallel gate tracks, as set out above. The inverter of the first half-cell may be coupled to a first instance of the first power rail, and the inverter of the second half-cell may be coupled to a second instance of the first power rail. The first and second instances of the first power rail may be configured as a respective buried power rail extending along a bottom and top edge of the respective bit cell. The inverters of the first and second half-cells may be coupled to a same (single) instance of the second power rail. In some examples, the instance of the second power rail may be configured as a buried power rail (BPR) extending along a midline of the respective bit cell. By configuring the power rails as the BPRs, routing resources may be freed up for routing bit lines and word lines in the interconnect level above the respective bit cells.

In some examples, the top devices are finFET devices, and the instance of the second power rail may be configured as a metal line arranged in a routing track of an interconnect level above the bit cell. In addition, the first bit line and the first complementary bit line may be configured as buried signal lines, arranged between the first and second instances of the first power rail. By burying two of the bit lines and shifting the second power rail to the interconnect structure, the number of tracks that need to be routed above the bit cell may be reduced by one. This may further facilitate scaling since the routing tracks may then not limit the cell height reduction enabled by configuring the top devices as finFET devices.

In some embodiments, the routing track may be a mid track of a set of routing tracks of the interconnect level and associated with the bit cell. The set of routing tracks extend along the cell width dimension and further include first and second edge tracks overlapping a top and bottom edge of the bit cell, respectively, a first and second off-center track arranged on opposite sides of the mid track, a third off-center track arranged between the first off-center track and the first edge track, and a fourth off-center track arranged between the second off-center track and the second edge track.

In these embodiments, a first and second instance of the first word line (WL-A) may be arranged in the first and second edge tracks, respectively.

In these embodiments, a first and second instance of the second word line (WL-B) may be arranged in the third and fourth off-center tracks, respectively.

In these embodiments, the second bit line and the second complementary bit line may be arranged in the first and second off-center tracks, respectively.

### BRIEF DESCRIPTION OF THE DRAWINGS

This and other aspects of the disclosed technology will now be described in more detail, with reference to the appended drawings showing embodiments of the disclosed technology.

FIG. 1 illustrates an example of a diagram showing dual-port (8T) to single-port (6T) bit cell footprint ratios for different device nodes and types.

FIG. 2 illustrates an example of a circuit diagram of a conventional 8T SRAM bit cell with 6 NMOS and 2 PMOS devices.

FIG. 3 illustrates an example of a circuit diagram of an SRAM device including a CFET-based 8T SRAM bit-cell with 4 NMOS and 4 PMOS devices according to an implementation.

FIG. 4 illustrates an example of a schematic perspective view of a CFET device.

FIGS. 5a-5f illustrate examples of cross-sections of various implementations of a CFET device.

FIGS. 6a-6c illustrates an example of a SRAM device, including a bit cell according to an implementation.

FIGS. 7a-7c illustrate an example of a SRAM device, including a bit cell according to a further implementation.

FIGS. 8a-8c illustrate an example of an SRAM device, including a bit cell according to a further implementation.

### DETAILED DESCRIPTION OF CERTAIN ILLUSTRATIVE EMBODIMENTS

Implementations and examples of SRAM devices and bit cells will below be described with reference to the drawings. The drawings are only schematic and the relative dimensions of some structures and layers may be exaggerated and not drawn to scale. Rather the dimensions may be adapted for illustrational clarity and to facilitate understanding. When present in the figures, the indicated axes X, Y and Z consistently refer to a first horizontal or lateral direction, a second horizontal or lateral direction, and a vertical direction, respectively. As used herein, the terms “horizontal” and “lateral” refer to directions parallel to (a main surface of) a supporting substrate of the memory structure. The term “vertical” refers to a direction parallel to a normal direction of (the main surface of) the substrate, e.g., transverse to the substrate. The first horizontal direction X may, for example, correspond to channel direction, or equivalently, a channel or gate length of the CFET devices. In embodiments of bit cells set out below, wherein the X direction may additionally correspond to a width dimension of a bit cell (meaning that the channel direction of the CFET devices of the bit cells coincides with the width dimension of the bit cell). The second horizontal direction Y may in turn correspond to cell-height dimension of a bit cell.

As described herein, a complementary field-effect transistor (CFET) refers to a transistor device having a complementary pair of FETs, where the FETs can be stacked on top of each other (e.g., an n-channel metal-oxide-semiconductor (NMOS) device stacked on top of a p-channel metal-oxide-semiconductor (PMOS) device or vice versa). The CFET allows for a reduced footprint compared to a traditional side-by-side arrangement of a p-channel field-effect transistor (pFET) and an n-channel field-effect transistor (nFET). These two devices and contact levels provided by the CFET (e.g., a “2-level middle-of line/MOL”) further enable reduced routing layer usage (e.g., in the back-end-of line/BEOL). Thus, the CFET facilitates the realization of area efficient circuitry.

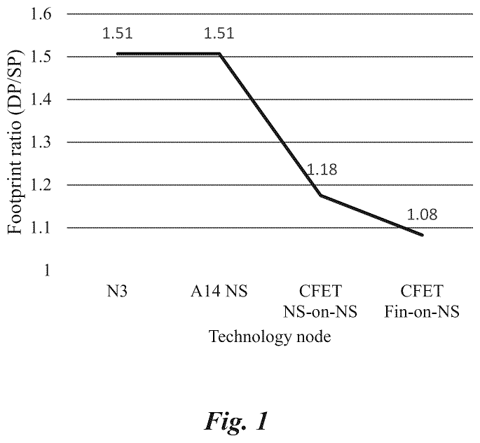

FIG. 1 shows the dual-port to single-port SRAM bit-cell footprint ratio for various technology nodes and device types. Due to the extra two transistors in a 8T bit-cell, the inability to stack devices in non-CFET nodes results in a typical footprint ratio of 1.51. In CFET technology, due to vertically stacking two transistors (e.g., NMOS over PMOS), the footprint ratio of dual-port (8T) to single-port (6T) bit-cells can be as low as about 1 (e.g., a theoretical ratio). This is because the extra two transistors in the 8T bit-cell can be stacked on the pass-gates of the 6T bit-cell without requiring additional area over the 6T CFET bit-cell. Achieving this ratio can make the 8T bit-cell a preferred choice in designing on-chip memories in modern SoCs, as it offers more functionality than a 6T single-port bit-cell within the same physical footprint. Although 6T SRAM bit-cell designs based on stacked complementary transistor pairs have been proposed, there is a need for a circuit design for an 8T dual-port SRAM that is both compatible with the CFET device architecture and capable of achieving a compact footprint with a footprint ratio of about 1 (e.g., theoretical dual-port to single-port bit-cell footprint ratio of 1).

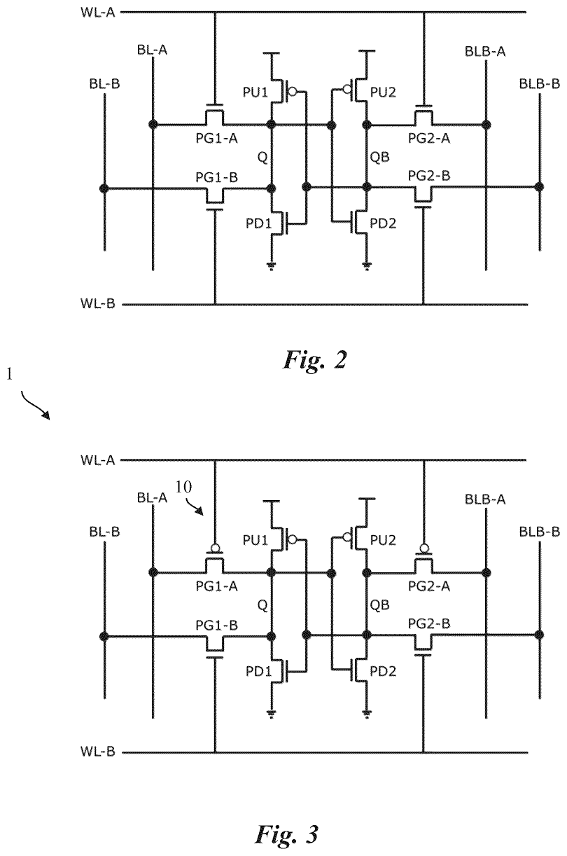

FIG. 2. is a circuit diagram of a conventional dual 8T SRAM bit cell which may be implemented using conventional non-CFET devices, 6 NMOS devices and 2 PMOS devices. The bit cell includes two cross-coupled inverter pairs, each including a PMOS pull-up (PU) device PU1, PU2 and an NMOS pull-down (PD) device PD1, PD2. The bit cell further includes two NMOS access transistors or pass-gate (PG) devices for each port (e.g., Port A: PG1-A, PG2-A and Port B: PG1-B, PG2-B). Since the PG devices of each port are independently connected to their respective word lines WL-A, WL-B and bit lines BL-A, BLB-A, BL-B, BLB-B, the storage nodes Q, QB formed by the cross-coupled inverters can be accessed simultaneously by the two ports.

As further illustrated in FIG. 2, in the conventional non-CFET device 8T SRAM bit cell, there would be no benefit to the bit cell footprint from switching the access NMOS transistor to PMOS, having an NMOS access transistor for port A and a PMOS access transistor for port B, or vice versa. Meanwhile, as realized by the inventors, for CFET devices, the conventional approach (e.g., having 6 NMOS and 2 PMOS devices or 6 PMOS and 2 NMOS devices) would not be effective as it would result in a larger CFET 8T bit cell footprint.

FIG. 3 illustrates an example of a circuit diagram of an SRAM device 1 including a CFET-based 8T SRAM bit-cell with 4 NMOS and 4 PMOS devices in accordance with embodiments disclosed herein. For example, the present technology provides a CFET-based 8T bit cell with an equal number of NMOS and PMOS devices (e.g., 4 NMOS and 4 PMOS devices). As illustrated in FIG. 3, the access transistors, PG1-A (for port A) and PG2-A (for port B), are PMOS (PG1-B) and NMOS (PG2-B) devices, respectively. This can allow the proposed bit cell (e.g., the CFET-based 8T SRAM bit-cell) to more efficiently utilize the CFET device architecture, thereby enabling a small CFET 8T bit cell layout. This may be appreciated more fully in view of the following.

As disclosed herein, the term “CFET” device refers to a device including a bottom FET device of a first conductivity type and a top FET device of a second conductive type opposite the first conductivity type stacked on top of the bottom FET device, e.g. an NMOS top device stacked on top of a PMOS bottom device, or vice versa. For conciseness the bottom FET device and the top FET device may interchangeably be referred to as a bottom device and a top device, respectively.

A CFET device may be provided in a split gate configuration with separate (e.g., disconnected) gates for the bottom device and the top device. For example, a CFET device with a split gate configuration includes a bottom gate for the bottom device and a top gate for the top device being separate from the bottom gate. In some embodiments, a CFET device may also be provided in a common gate configuration with a common gate shared by the bottom and top devices. For example, a CFET device with a common gate configuration includes a common gate shared by the bottom and top devices. The common gate may thus include a bottom gate portion for the bottom device and a top gate portion for the top device coupled to the bottom gate portion.

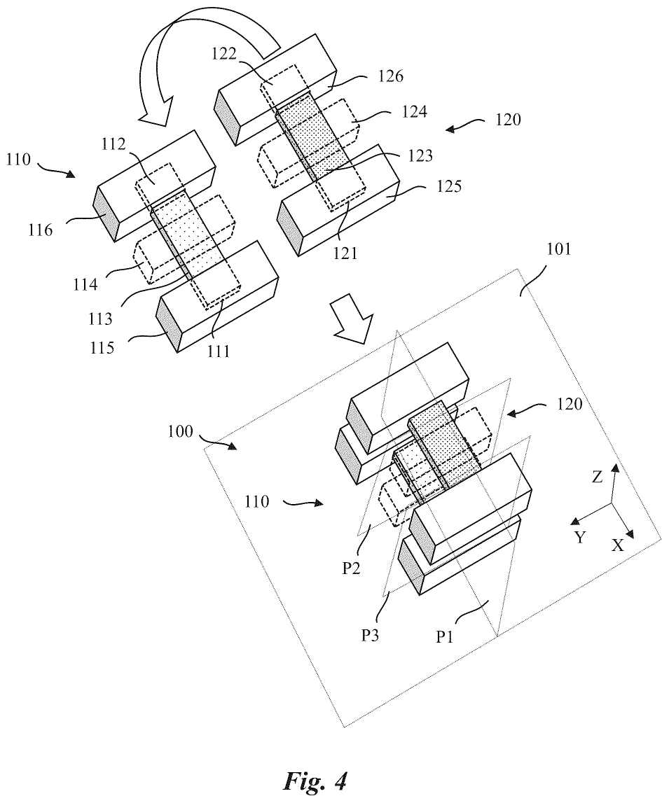

FIG. 4 illustrates an example of a schematic perspective view of a CFET device. For example, FIG. 4 includes a schematic perspective view of a CFET device 100, having a bottom device 110 and a top device 120 stacked on top of the bottom device 110 (e.g., the top device 120 is stacked on the bottom device 110). The bottom device 110 defines a bottom level or bottom tier of the CFET device 100, and the top device 120 defines a top level or top tier of the CFET device 100. In some embodiments, the bottom device 110 may be a PMOS device, and the top device 120 may be an NMOS device, or vice versa (e.g., the bottom device 110 may be a NMOS device, and the top device 120 may be an PMOS device).

The CFET device 100 is arranged on a substrate, schematically indicated by reference sign 101. The substrate 101 may be of a conventional type suitable for Complementary Metal-Oxide-Semiconductor (CMOS) devices, for example, a bulk substrate of a semiconductor such as silicon (Si), silicon germanium (SiGe), or a silicon-on-insulator (SOI) substrate, to give a few non-limiting examples (e.g., without limitation).

The bottom device 110 includes a first source/drain (S/D) region 111, a second S/D region 112, a channel structure 113 extending between the first S/D region 111 and the second S/D region 112, and a gate 114 surrounding the channel structure 113. The top device 120 includes a first S/D region 121, a second S/D region 122, a channel structure 123 extending between the first S/D region 121 and the second S/D region 122, and a gate 124 surrounding the channel structure 114. For the purpose of description, the labels “bottom” and “top” may in the following be used to refer to an element of, or associated with, the bottom device 110 and the top device 120, respectively, such as first S/D regions 111/121, the second S/D regions 112/122, the channel structures 113/123, the gates 114/124, etc.

The top device 120 is stacked on top of the bottom device 110 such that the first top S/D region 121 overlaps the first bottom S/D region 111, the second top S/D region 122 overlaps the second bottom S/D region 112, and the top channel structure 123 overlaps the bottom channel structure 113. The “overlap” disclosed herein refers to an overlap as seen along the vertical direction Z. Accordingly, as shown in FIG. 4, the first S/D regions 111/121, the second S/D regions 112/122, and the channel structures 113/123 intersect a common (geometrical) vertical plane P1 (parallel to the XZ-plane).

As further illustrated in FIG. 4, a respective S/D contact 115, 116, 125 and 126 may as shown be arranged on each of the first bottom S/D region 111, the second bottom S/D 112, the first top S/D region 121, and the second top S/D region 122, respectively. Analogous to the first S/D regions 111/121 and the second S/D regions 112/122, the first top S/D contact 125 may overlap the first bottom S/D contact 115, and the second top S/D contact 125 may overlap the second bottom S/D contact 115.

In FIG. 4, the channel structures 113, 123 are merely schematically shown, as examples. In some embodiments, the channel structures 113, 123 may include a number of (e.g., one or more) channel nanosheets. For example, the CFET device 100 may include a bottom nanosheet FET (NSHFET) 110 and a top NSHFET 120. In an alternative CFET design, the channel structure 113 of the bottom device 110 may include a number of channel nanosheets, and the channel structure 123 of the top device 120 may include a semiconductor fin (e.g., a fin-shaped channel structure). For example, the CFET device 100 may include a bottom nanosheet NSHFET 110 and a top FinFET 120.

The bottom gate 114 may surround the bottom channel structure 113, partly (such as on three-sides) or completely to define a gate-all-around (GAA) for one or more channel nanosheets of the bottom channel structure 113. The top gate 124 may surround the top channel structure 123, partly (such as on three-sides) or completely to define a gate-all-around (GAA) for one or more channel nanosheets of the top channel structure 123.

The channel structures 113, 123 include a semiconductor material such as a group IV semiconductor, e.g. Si, Ge, or SiGe. However also other materials are possible such as group III-V semiconductors (e.g. indium phosphide (InP), indium arsenide (InAs), gallium arsenide (GaAs), and gallium nitride (GaN)).

The S/D regions 111, 112, 121, 122 may include or be formed by epitaxial S/D bodies. The epitaxial S/D bodies may include doped semiconductor material (e.g. Si, germanium (Ge), SiGe), e.g. epitaxially grown on the channel structures 113, 123. The S/D regions 111, 112, 121, 122 may alternatively be formed by doped portions of the channel structures 113, 123.

The S/D contacts 115, 116, 125, 126 may include one or more contact metals, such as tungsten (W), aluminum (Al), ruthenium (Ru), molybdenum (Mo), or cobalt (Co). In some examples, the one or more contact metals can include barrier metals, such as tantalum (Ta), titanium nitride (TiN), or tantalum nitride (TaN).

The gates 114, 124 may include one or more gate metal layers, such as one or more work function metal (WFM) layers and/or a gate fill layer. For example, the WFMs include n-type and p-type effect WFMs, such as TiN, TaN, titanium aluminum alloy (TiAl), titanium aluminum carbide (TiAlC), or tungsten carbonitride (WCN), or combinations thereof. The fill metals can include, for example, W and Al. A gate dielectric layer (not shown in FIG. 4) is provided (e.g., disposed) between the gates 114, 124 and the respective channel structures 113, 123. In some examples, the gate dielectrics include gate dielectrics, such as a high-k dielectric, for example, hafnium dioxide (HfO2), lanthanum oxide (LaO), aluminum oxide (AlO), or Zirconium Oxide (ZrO).

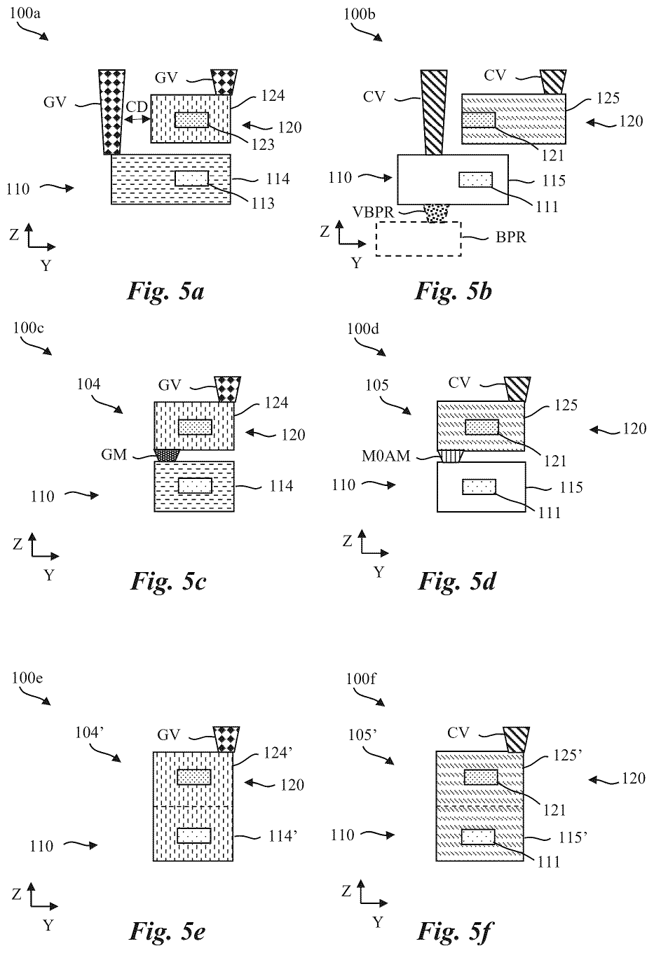

In some embodiment, the CFET device 100, as shown in FIG. 4, can have a split gate configuration. In some embodiments, the CFET device 100 can have separate (e.g., disconnected) first S/D contacts 115, 125 and separate second S/D contacts 116, 126. In some embodiments, the CFET device 100 can also have various configurations, as illustrated in FIG. 5a-5f. Each of the FIGS. 5a, 5c, and 5e shows a cross-section of a respective configuration of a CFET device taken across the channel structures 113, 123 and along the gates 114, 124, for example, along plane P2 indicated in FIG. 4. In some embodiments, each of the FIGS. 5b, 5d, and 5f illustrates a cross-section of a respective configuration of a CFET device taken across the sources 111, 121 and the contacts 115, 125, for example, along plane P3 indicated in FIG. 4. Although FIGS. 5b, 5d, and 5f show cross-sections at the side of first S/D regions of CFET devices, the configurations shown in these figures may be applied in a corresponding manner to second opposite S/D regions of the CFET devices.

FIG. 5a shows a CFET device 100a having a split gate configuration with separate bottom and top gates 114, 124. In some embodiments, the bottom gate 114 includes a side gate portion or gate extension, protruding outside the top gate 124 to define a landing portion for a gate via GV. The gate extension can extend laterally with respect to the channel structures 113, 123, for example, along the Y-direction. The dimension or extent of the gate extension may vary in accordance with the available space adjacent the CFET device 100a in a given circuit implementation. However, the minimum extension of the gate extension can be determined by the critical dimension (CD) indicated in FIG. 5a, which corresponds to the minimum separation between the GV and the top gate 124. The top gate 124 may be contacted by a separate GV.

FIG. 5b shows a CFET device 100b, including separate first S/D contacts 115, 125. In some examples, the bottom contact 115 includes a side contact portion or contact extension, protruding outside the top contact 125 to define a landing portion for a contact via CV. The contact extension extends laterally with respect to the channel structures 113, 123, for example, along the Y-direction. The dimension or extent of the contact extension may vary in accordance with the available space adjacent the CFET device 100b. However, the minimum extension of the contact extension is determined by the CD indicated in FIG. 5b, which corresponds to the minimum separation between the CV and the top contact 125. The top contact 125 may as shown be contacted by a separate CV.

FIG. 5b further shows an alternative contact scheme for the bottom contact 115. In some examples, the bottom contact 115 is contacted from a backside of the substrate or device by a via-to-BPR (VBPR), also called power via (PV). The VBPR may in turn be connected to a backside, or buried, power rail (BPR). The term BPR disclosed herein used in an inclusive sense to refer to a power rail regardless of whether it is formed in a trench embedded in a substrate at the front end of line, or as part of a backside power distribution network (PDN) formed on the backside of the substrate at the back end of line.

FIG. 5c shows a CFET device 100c, having a common gate configuration, thus including a common gate 104 shared by the bottom and top device 110, 120. The common gate 104 includes a bottom gate portion 114 and a top gate portion 124 coupled to the bottom gate portion 114 by a gate merge via (GM). The GM is arranged intermediate the bottom gate portion 114 and the top gate portion 124 and extends therebetween (e.g., vertically along the Z-direction) to interconnect the gate portions 114 and 124. The common gate may be as shown be contacted by a GV landing on the top gate portion 124.

FIG. 5d shows a CFET device 100d, including a common S/D contact 105 shared by the bottom and top device 110, 120, for example, by the first bottom and top S/D regions 111, 121. The common S/D contact 105 includes a bottom contact portion 115 and a top contact portion 125 coupled to the bottom contact portion 115 by a contact merge via M0AM (e.g., M0A denotes the local interconnect level of the CFET device 100d). The M0AM can be arranged intermediate the bottom contact portion 115 and the top contact portion 125 and extends therebetween (e.g., vertically along the Z-direction) to interconnect the contact portions 115 and 125. The bottom contact portion 115 can be arranged on (e.g., surrounds) the bottom source 111, and the top contact portion 125 is arranged on (e.g., surrounds) the top source 121. The common contact 105 may as shown be contacted by a CV landing on the top contact portion 125. While not shown in FIG. 5d, in some embodiments, the common contact 105 can be contacted from the backside, for example, in an analogous manner to FIG. 5b.

FIG. 5e shows a CFET device 100e, including a common gate 104′, having a bottom gate portion 114′ and a top gate portion 124′. The bottom gate portion 114′ and the top gate portion 124′ form part of the continuous common gate 104′ (e.g., being an integrally formed gate body). FIG. 5e shows a further example of a CFET device 100e, including a common gate shared by the bottom device 110 and the top device 120. As shown in FIG. 5c, the bottom gate portion 114′ corresponds to the portion of the common gate 104′ surrounding the channel structure of the bottom device 110, and the top gate portion 124′ corresponds to the portion of the common gate 104′ surrounding the channel structure of the top device 120. In some embodiments, the common gate may be contacted by a GV landing on the top gate 124. While FIG. 5e shows a same fill pattern for the bottom and top gates 114, 124, it is also possible to form the bottom and top gate portions 114, 124 of different compositions, using appropriate process techniques (e.g., a “split-replacement metal gate (RMG)” CFET process).

FIG. 5f shows a CFET device 100f, including a common S/D contact 105′, having a bottom contact portion 115′ and a top contact portion 125′. The bottom and top contacts 115, 125 form part of the continuous common contact 105′ (e.g., being an integrally formed contact body). Thus, FIG. 5f shows a further example of a CFET device 100f, including a common S/D contact 105′ shared by the bottom device 110 and the top device 120. As shown in FIG. 5f, the bottom contact portion 115′ corresponds to the portion of the common contact 105′ arranged on (e.g., surrounding) the bottom source 111, and the top contact portion 125′ corresponds to the portion of the common contact 105′ arranged on (e.g., surrounding) the top source 121. The common S/D contact 105′ may be contacted by a CV landing on the top contact portion 125. While FIG. 5f shows a same fill pattern for the bottom and top contact portions 115′, 125′ it is also possible to form the bottom and top contact portions 115′, 125′ of different compositions, using appropriate process techniques.

The split gate configuration shown in FIG. 5a may, for instance, be obtained using the “sequential CFET process”. In the sequential CFET process the bottom and top devices are formed sequentially and results in a split bottom and top gates.

The common gate configuration of FIG. 5c may be achieved by supplementing the standard sequential CFET process with additional process steps to form the gate merge via GM for interconnecting the bottom and top gate portions. The common gate configuration shown in FIG. 5e may be obtained using the “monolithic CFET process.” In some cases, for example, in the monolithic CFET process, the bottom and top devices are processed in parallel, top-down. While the standard monolithic CFET process results in a common gate configuration, it may be supplemented with additional process steps to enable a split gate configuration for selected CFET devices (e.g. bottom gate recess, bottom gate capping, followed by top gate formation).

Common or separate source or drain contacts may be formed using conventional CFET device processing techniques. For instance, separate (first or second) S/D contacts may be formed by depositing contact metal on the (first or second) S/D regions, etching back the contact metal to a level below the (first or second) top S/D region, capping the remaining contact metal on the (first or second) bottom S/D region with an insulating layer and subsequently depositing contact metal on the (first or second) top S/D.

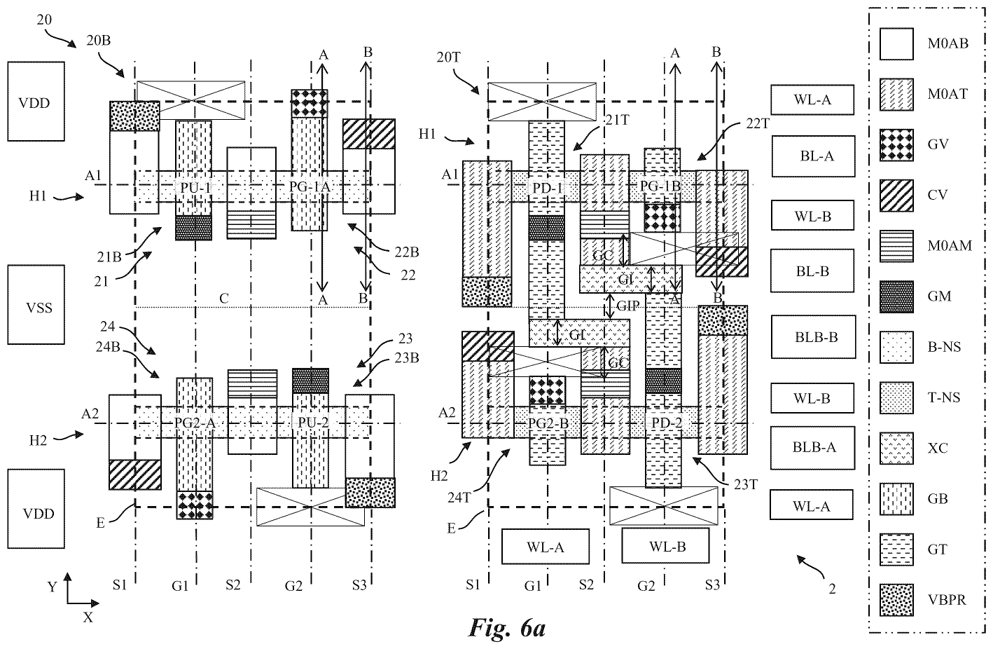

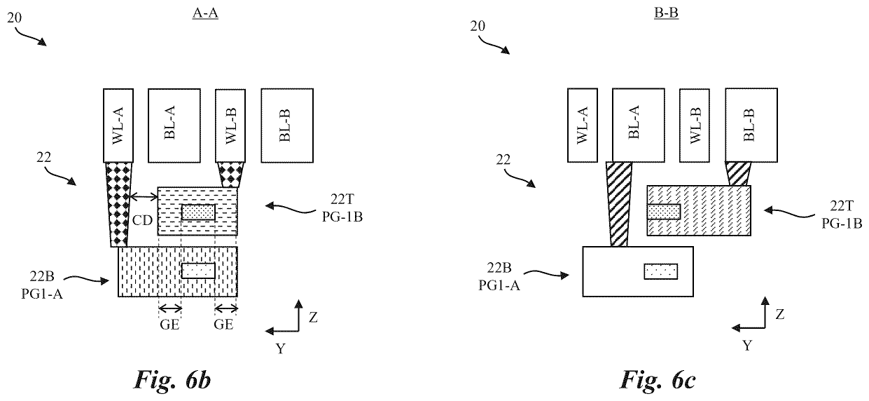

Various example implementations of SRAM devices with CFET-based 8T dual-port bit cells will now be described with reference to FIGS. 6a-6c, 7a-7c and 8a-8c. A common feature is that the bit cells include a first half-cell H1 and a second half-cell H2, each half-cell including a first and a second CFET device, wherein the first CFET device includes a common gate shared by its bottom and top device and is configured as an inverter cross-coupled to the inverter of the other half-cell (corresponding to the cross-coupled inverter pairs PU1-PD1 and PU2-PD2 in FIG. 3). Further, the bottom device of the second CFET device of each half-cell is configured as a first pass-gate (corresponding to PG1-A and PG2-A in FIG. 3) for a first port of the respective half-cell (corresponding to BL-A and BLB-A in FIG. 3) and includes a bottom gate coupled to a first word line (corresponding to WL-A of FIG. 3). Further, the top device of the second CFET device of each half-cell is configured as a second pass-gate (corresponding to PG1-B and PG2-B in FIG. 3) for a second port of the respective half-cell (corresponding to BL-B and BLB-B in FIG. 3) and includes a top gate which is separate from the bottom gate and is coupled to a second word line (corresponding to WL-B in FIG. 3). The respective bit cell designs will described in further detail in the following.

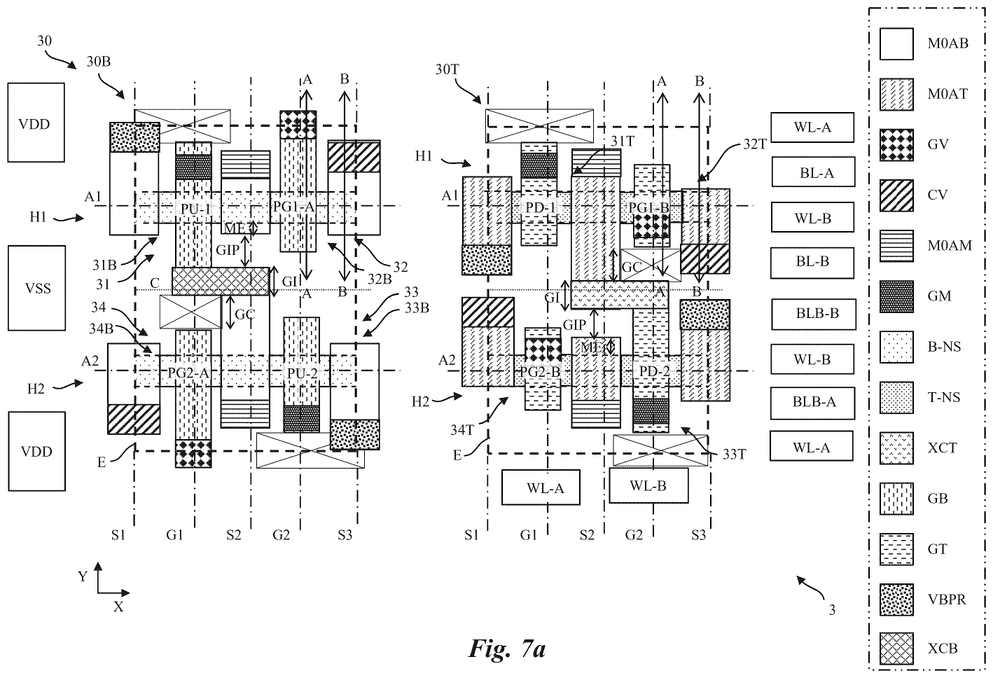

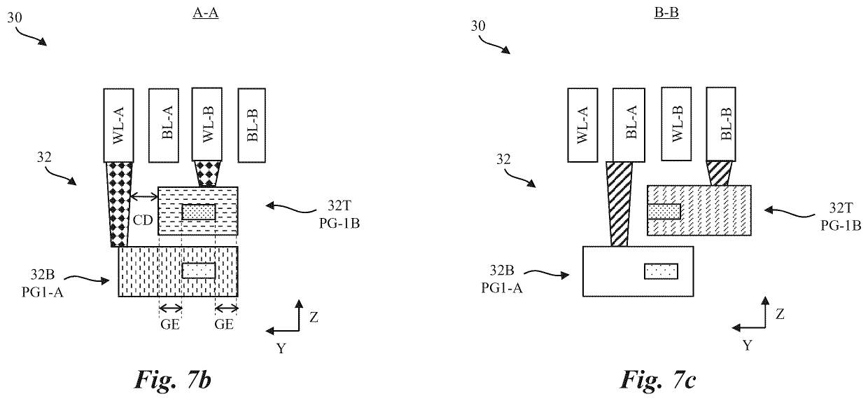

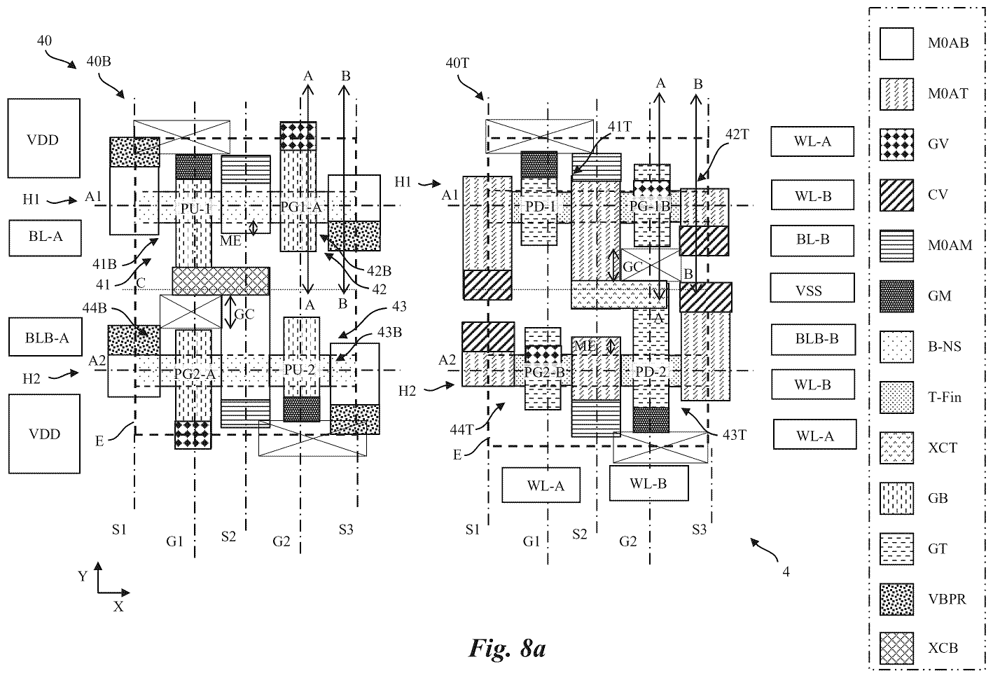

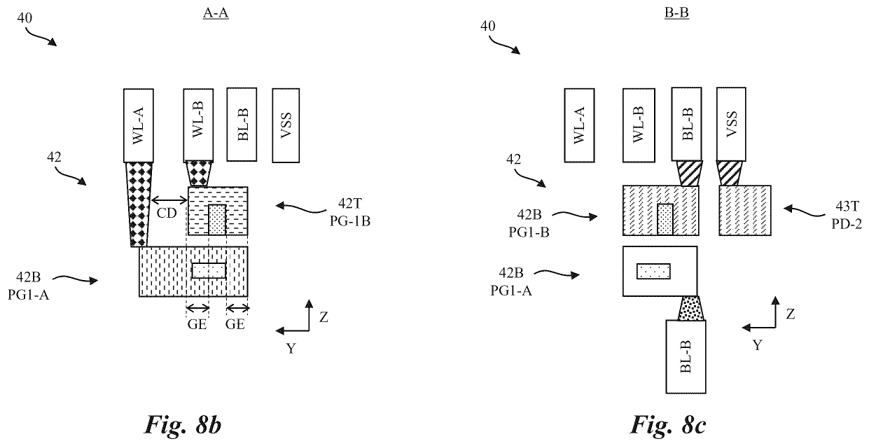

In FIG. 6a, the first and second CFET device of the first half-cell H1 and the second half-cell H2 have reference signs 21 and 22, and 23 and 24, respectively. In FIG. 7a, the first and second CFET device of the first half-cell H1 and the second half-cell H2 have reference signs 31 and 32, and 33 and 34, respectively. In FIG. 8a, the first and second CFET device of the first half-cell H1, and the second half-cell H2 have reference signs 41 and 42, and 43 and 44, respectively.

Further, the reference signs and labels in the figures have the following common meaning:

Reference sign E indicates the edges of a bit cell. Reference signs H1 and H2 indicate first and second half-cells of a bit cell. Direction X indicates a cell width dimension and, equivalently, a channel direction for the CFETs of the bit cell, and direction Y indicates a cell height dimension. Lines A1 and A2 indicate first and second active tracks of a bit cell extending in parallel in the cell width dimension X. Lines G1 and G2 indicate first and second gate tracks of a bit cell extending in parallel in the cell height dimension Y. Lines S1-S3 indicate respective S/D contact tracks extending in parallel in the cell height dimension Y, wherein the first and third S/D contact tracks S1, S3 extend along opposite edges of the bit cell and the second S/D contact track S3 extends midway between G1 and G2. Crossed out rectangular regions indicate gate cut regions (GC).

The fill patterns used in the figures have the following meaning:

“M0AB” is the local interconnect level of the bottom tier. Hence, a feature with the fill pattern associated with “M0AB” is a contact located in located in the bottom tier (e.g. a bottom S/D contact). M0AT is the local interconnect level of the top tier. Hence, a feature with the fill pattern associated with M0AT is a contact located in the top tier (typically a top S/D contact). M0AB and M0AT are each included in the local interconnect level “M0A” of the bit cell.

The fill pattern associated with “GV” is used to indicate a gate via extending between a bottom gate/bottom gate portion (“GB”) and an upper interconnect level, or a top gate/top gate portion (“GT”), e.g. as shown in FIG. 5a. The upper interconnect level may be the first interconnect level above the local interconnect level M0A (sometimes denoted “M0” or “MINT”, depending on context).

The fill pattern associated with “CV” indicates a contact via extending between M0AB or M0AT and an upper interconnect level, e.g. as shown in Figi. 5b. Like for the gate via GV, the upper interconnect level may be the first interconnect level above the local interconnect level M0A (e.g. M0).

The fill pattern associated with “M0AM” is a local interconnect merge layer or via, interconnecting a contact in M0AB with a contact in M0AT, e.g. as shown in FIG. 5d.

The fill pattern associated with “GM” indicates a gate merge layer or via, interconnecting a bottom gate or bottom gate portion (GB) with a top gate or top gate portion (GT), e.g. as shown in FIG. 5c.

The fill pattern associated with “B-NS” indicates a nanosheet or nanosheet stack in the bottom tier B. The fill pattern associated with “T-NS” indicates a nanosheet or nanosheet stack in the top tier T. The fill pattern associated with “T-Fin” indicates a fin or a fin-shaped channel structure in the top tier T.

The fill pattern associated with “XC” indicates a cross-couple merge layer or metal strap formed on top of the M0AT and included in the local interconnect level M0A. It may also be referred to as a gate-spacer merge layer as it may be arranged to extend over and across a gate spacer to merge or interconnect a gate with a S/D contact in M0AT.

The fill pattern associated with “VBPR” indicates a via-to-BPR. In instances where a VBPR is shown over a contact in M0AT, it is to be understood that there is a further via extending from M0AT through the local interconnect level M0AB and landing on the VBPR.

The rectangular boxes on the left-hand side of the bit cell in FIGS. 6a, 7a and 8a indicate instances of BPRs extending in parallel in the Y-direction underneath the bit cell.

The rectangular boxes on the right-hand side of the bit cell indicate routing tracks in a first interconnect level above the local interconnect level M0A (e.g., M0) extending in parallel in the Y-direction, within the footprint of the bit cell. As is known to the skilled person, a metal line (e.g., word line or bit line) arranged in any given routing track in the first interconnect level (or second interconnect level) need not extend along the full width dimension (or full height dimension) of the bit cell but should at least extend so as to define an overlap with any contact via CV, gate via GV arranged along the routing track, so as to enable a coupling between the metal line and the underlying contact or gate.

The rectangular boxes below the bit cell indicate routing tracks in a second interconnect level above the first interconnect level (e.g. M1). Metal lines arranged in any given routing track in the second interconnect level may be coupled to a metal line in a correspondingly labeled routing track in the first interconnect level (e.g. by a via in M1).

FIG. 6a-c shows an SRAM device 2 including a CFET-based dual-port 8T bit cell according to a first design.

The S/D regions, S/D contacts and gates of the first CFET device 21 and the second CFET device 22 of the first half-cell H1 are as shown arranged along a first active track A1. Correspondingly, the S/D regions, S/D contacts and gates of the first CFET device 23 and the second CFET device 24 of the second half-cell H2 are arranged along a second active track A2. Further, the common gate of the first CFET device 21 of the first half-cell H1 and the split bottom and top gates of the second CFET device 24 of the second half-cell H2 are arranged along a first gate track G1, and the common gate of the first CFET device 23 of the second half-cell H2 and the split bottom and top gates of the second CFET device 22 of the first half-cell H1 are arranged along a second gate track G2.

Each bottom device 21B, 22B, 23B, 24B and each top device 21T, 22T, 23T, 24T of the CFET devices 21, 22, 23, 24 includes a first S/D region and a second S/D region. The first S/D regions of the CFET devices 21, and 24 are arranged along the first S/D contact track S1. The first S/D regions of the CFET devices 22, and 23 are arranged along the third S/D contact track S3. The second S/D regions of the CFET devices 21, 22, 23, 24 are arranged along the second S/D contact track S2.

The first half-cell H1 includes a first common S/D contact arranged between the first and second CFET 21, 22 of the first half-cell H1 and shared by their respective second S/D regions. The second half-cell H2 includes a second common S/D contact arranged between the first and second CFET devices 23, 24 of the second half-cell H2 and shared by their respective second S/D regions. The first and second common S/D contacts are arranged along the second S/D contact track S2.

The first S/D regions of each CFET device 21, 22, 23, 24 are each coupled to respective S/D contacts which are split between the bottom and top tiers 20B, 20T. The first S/D regions of the bottom and top devices of the CFET devices 21, 22, 23, 24 are hence individually contacted. The S/D contacts coupled to the first S/D regions of the first CFET device 21 of the first half-cell H1 and the first S/D regions of the second CFET device 24 of the second half-cell H2 are arranged along the first S/D contact track S1. The S/D contacts coupled to the first S/D regions of the second CFET device 22 of the first half-cell H1 and the first S/D regions of the first CFET device 23 of the second half-cell H2 are arranged along the third S/D contact track S3.

As per the illustrated example, the bottom tier 20B and top tier 20T, respectively, include the four PMOS devices (PU-1, PU-2, PG1-A, and PG2-A) and four NMOS devices (PD-1, PD-2, PG1-B and PG2-B).

The two inverters are created by merging the drains of PU-1 (PU-2) and PD-1 (PD-2) of the first CFET device 21 (and 23) using the M0A merge layer M0AM and their top and bottom gates using the gate merge layer GM.

The gate-spacer merge layer XC on the top tier 20T is used to enable the inverter cross-coupling. More specifically, the first and second common S/D contacts each includes, as shown, a respective contact extension protruding along the cell-height dimension X towards the other common S/D contact. Further, the common gates of the first CFET devices 21, 23 each include a gate extension protruding towards the (split) gates of the second CFET devices 22, 24 of the opposite half-cell H1, H2.

The gate extension of the common gate of first CFET device 21 of the first half-cell H1 protrudes such that its tip portion is separated from a tip portion of the bottom and top gates of the second CFET device 24 of the second half-cell H2 by a first gate cut region GC. Correspondingly, the gate extension of the common gate of the first CFET device 23 of the second half-cell H2 may protrude such that its tip portion is separated from a tip portion of the bottom and top gates of the second CFET device 22 of the first half-cell H1 by a second gate cut region GC.

A first metal strap XC extends in the Y-direction to bridge a distance between, and thus interconnect the respective tip portions of the gate extension of the common gate of the first CFET device 21 of the first half-cell H1 and the contact extension of the second common S/D contact of the second half-cell H2. Correspondingly, a second metal strap XC extends in the Y-direction to bridge the distance between, and thus interconnect the respective tip portions of the gate extension of the common gate of the first CFET device 23 of the second half-cell H2 and the contact extension of the first common S/D contact of the first half-cell H1.

The PMOS pass gates for port A (PG1-A and PG2-A) are arranged in the bottom tier 20B underneath the NMOS pass gates for port B (PG1-B and PG2-B). The pass gates for port A and port B can be controlled independently as the top and bottom gates of the respective second CFETs 22 and 24 are split.

The layout of the bottom tier 20B and the cross-sectional view of FIG. 6b (e.g., taken along A-A of FIG. 6a) demonstrate the split-gate configuration of the stacked pass gates PG1-A, PG1-B, the minimum gate extension GE, and the requirement for 1CD (critical dimension) spacing from the top gate TG to the gate via GV to the bottom gate BG for connecting to WL-A.

The SRAM device 2 includes as shown two instances of a pull-up power rail (“first power rail”) VDD configured as BPRs extending in the cell width dimension X along opposite edges of the bit cell 20. The pull-up devices PU-1 and PU-2 are coupled to respective instances of the pull-up power rail VDD by a respective VBPR.

The SRAM device 2 further includes an instance of a pull-down power rail (“second power fail”) VSS, also configured as a BPR and extending in the cell width dimension X along a midline C of the bit cell 20. The pull-down devices PD-1 and PD-2 are coupled to instance of the pull-down power rail VSS by a respective VBPR.

The bit cell interconnections are otherwise as follows:

The bit cell 20 is associated with eight routing tracks, each including a respective instance of a first or second word line WL-A, WL-B, first or second bit lines BL-A, BL-B, or first or second complementary bit lines BLB-A, BLB-B. The first and second instances of the first word line WL-A may as shown be arranged in respective edge tracks, overlapping the top and bottom edges of the bit cell 20. This allows the instances of the first word lines WL-A to be shared with neighboring bit cells.

The split bottom and top S/D contacts (in M0AB and M0AT, respectively) of the first and second pass-gates PG1-A, PG1-B of the first half-cell H1 are coupled to a first and second bit line BL-A, BL-B, respectively, (arranged in M0) by a respective contact via CV. The contact vias are as shown arranged at opposite lateral sides of the first active track A1.

The split bottom and top gates “B an′ GT of the first and second pass-gates PG1-A, PG1-B of the first half-cell H1 are coupled to a first instance of a first word line WL-A and a first instance of a second word line WL-B, respectively, (arranged in M0) by a respective gate via GV. The gate vias are as shown arranged at opposite lateral sides of the first active track A1.

The split bottom and top S/D contacts (in M0AB and M0AT, respectively) of the first and second pass-gates PG2-A, PG2-B of the second half-cell H2 are coupled to a first and second complementary bit line BLB-A, BLB-B, respectively, (arranged in M0) by a respective contact via CV. The contact vias are as shown arranged at opposite lateral sides of the second active track A2.

The split bottom and top gates GB and GT of the first and second pass-gates PG2-A, PG2-B of the second half-cell H2 are coupled to a second instance of the first word line WL-A and a second instance of the second word line WL-B, respectively, (arranged in M0) by a respective gate via GV. The gate vias are as shown arranged at opposite lateral sides of the second active track A2.

As may be appreciated from FIG. 6a-c, the bit cell height along the bit cell height dimension X is determined by the minimum gate-cut (GC), the minimum gate extension (GE), the nanosheet width (NSHW), the minimum gate internal spacer merge width (GI), the minimum space between the gate spacer merge layers (GIP), and the CD requirement for the gate via to the bottom gate. As an illustrative example, for a state of the art technology node, the total cell height becomes 136 nm:

$$Cell height = 2 \times GC + 4 \times GE + 2 \times NSHW + 2 \times GI + GIP + 3 \times CD = 2 \times 12 + 4 \times 9 + 2 \times 11 + 2 \times 9 + 9 + 3 \times 9 = 136 nm \qquad ( eq . 1 )$$

As may be appreciated, the parameter values in eq. 1 should only be considered as representative examples. However, the form of eq. 1 is of course applicable also for other values of the various parameters.

As shown in FIG. 6a-c, most of the signal routing and integration are enabled in the top tier 20T leaving the bottom tier 20B largely free. The cross-couple formation however necessitates two gate spacer merge layer widths GI and a spacing GIP, as shown by the above cell height equation. This limits the ability to down-scale the bit cell height. This limit can be avoided by enabling part of the cross-couple formation at the bottom tier, which is largely empty, instead of only at the top tier. Therefore, as illustrated for the SRAM device 3 and the bit cell 30 in FIG. 7a-c, the cross-couple formation is segmented into its partially integrations in the bottom tier 30B and at the top tier 30T. Compared to the layout in FIG. 6a-c, this layout design, however, requires both a bottom cross-couple merge layer (bottom metal strap) “XCB” and a top cross-couple merge layer (top metal strap) “XCT”.

More specifically, the gate extension of the common gate of the first CFET device 31 of the first half-cell H1 (first common gate) and the contact extension of the second common S/D contact of the second half-cell H2 are arranged in the bottom device tier 30B but not the top device tier 30T. Meanwhile, the gate extension of the common gate of the first CFET device 33 (second common gate) of the second half-cell H2 and the contact extension of the first common S/D contact are arranged in the top device tier 30T but not the bottom device tier 30B.

Accordingly, the gate extension of the first common gate is included in the bottom gate portion GB and protrudes relative to the top gate portion GT of the first common gate. Correspondingly, the contact extension of the second common S/D contact is included in the bottom contact portion (in M0AB) of the second common S/D contact and protrudes relative to the top contact portion (in M0AT) of the second common S/D contact. On the other hand, the gate extension of the second common gate is included in the top gate portion GT of the second common gate and protrudes relative to the bottom gate portion GB of the second common gate. Correspondingly, the contact extension of the first common S/D contact is included in the top contact portion (in M0AT) of the first common S/D contact and protrudes relative to the bottom contact portion (in M0AB) of the first common S/D contact.

As shown, the respective contact extensions may protrude past the midline C of bit cell 30. The cross-couple merge layer/first metal strap XC for the cross-coupling in the bottom tier 30B may be included in the local interconnect layer M0A and arranged on top of the bottom tier local interconnect layer M0AB.

The cross-couple merge layer/second metal strap XC for the cross-coupling in the top tier 30T may be included in the local interconnect layer M0A and arranged on top of the top tier local interconnect layer M0AT.

Furthermore, in order to avoid direct influence on the cell height and facilitate process integration, the respective M0A merge layers M0AM of the first and second common S/D contacts and the gate merge layers GM of the common gates of the first CFET devices 21 and 23 have been shifted towards the cell edges, to be arranged outside of the area between the first and second active tracks A1, A2, as shown in FIG. 7a. These two changes, e.g., enabling cross-coupling separately on the top and bottom tiers and removing M0A MRG from between device, lead to a bit cell height of 114 nm:

$$Cell height = GC + 3 \times GE + 2 \times NSHW + GI + GIP + 3 \times CD + M 0 A\_extn = 12 + 3 \times 9 + 2 \times 11 + 9 + 12 + 3 \times 9 + 5 = 114 nm \qquad ( eq . 2 )$$

which is 22 nm smaller than the layout design of FIG. 6a-c. The additional term M0A_extn (denoted ME in the figures) is the minimum extension of the S/D contacts in either M0AB or M0AT.

The dual-port 8T to single-port 6T ratio for the CFET NS-on-NS scheme bit cell design of FIG. 7a-c described above is 114 nm/97 nm (=1.18). To further scale the CFET dual-port 8T bit cell, the top nanosheets are in the bit cell 40 of SRMAM device 4 of FIG. 8a-c replaced by a Fin-NMOS device, to obtain first and second Fin-on-NS CFETs 41, 42, 43, 44 in each half-cell H1, H2. That is, the bottom devices of the CFET devices 41, 42, 43, 44 are configured as nanosheet-FETs and the top devices as finFETs. This enables a further reduction as will be explained in the following.

However, the Fin-on-NS bit cell height is insufficient for all of the routing tracks in the first interconnect level M0. Therefore, the second power rail VSS is shifted to the first interconnect level M0 and the bit lines of port A (BL-A and BLB-A) are configured as buried bit lines, arranged between the two instances of the first BPRs VDD as shown in cross-sectional view of FIG. 8b-c.

Accordingly, in contrast to the bit cell 30, the bit cell 40 is associated with only seven routing tracks of the first interconnect level M0. Like for the bit cell 30, a first and second instance of the first word line WL-A is arranged along first and second edge tracks. The second power rail VSS is arranged along a mid track (or center track). The second bit line BL-B and the second complementary bit line BLB-B are arranged in first and second off-center tracks, respectively, arranged on opposite sides of the mid track. The first and second instances of the second word line WL-B are arranged in third and fourth off-center tracks, respectively, the third off-center track being arranged between the first edge track and the first off-center track, and the fourth off-center track being arranged between the second edge track and the second off-center track.

Thus, inside the bit cells 30, 40, (e.g., between active tracks A1-A2), the dimensions of the layouts in FIGS. 7a and 8a are essentially identical, and is disregarding the nanosheet width NSHW and the fin width FW it given by: GE+GC+GI+GIP+M0A_extn.

Towards the edges of the bit cell 30, the remaining dimension is calculated as 2×(NSHW+GE+CD+0.5CD). The additional 0.5CD is introduced by the WL-A routing tracks in the first interconnect layer M0 layer of the WL which will be shared with the adjacent top and lower bit cells (not visible in FIG. 7a), which gives the cell height as calculated in eq. 2.

For the Fin-on-NS case of the bit cell 40, the cell height is governed by the layout design requirements of the top tier 40T only. This is because the gate extension GE required for the top Fin T-Fin begins at the edge of the fin (which is within the foot print of the bottom nanosheet B-NS) and extends over the bottom nanosheet B-NS. Consequently, the nanosheet width NSHW does not contribute to the cell height in this layout. Therefore, the remaining contribution to the cell height becomes 2×(FW+GE+CD+0.5×GC), which gives a total cell height as:

$$Cell height = ( GE + GC + GI + GIP + M 0 A\_extn ) + 2 \times ( FW + GE + CD + 0.5 \times GC ) = 2 \times GC + 3 \times GE + 2 \times FW + GI + GIP + 2 \times CD + M 0 A\_extn = 2 \times 12 + 3 \times 9 + 2 \times 5 + 9 + 12 + 3 \times 9 + 5 = 105 nm \qquad ( eq . 3 )$$

The 6T CFET bit cell height cannot be scaled by placing the Fin device on top. As a result, the bit cell footprint ratio of dual-port (8T) to single-port (6T) is 1.08, which is very close to 1 as the ratio that is theoretically possible in CFET device architecture.

The person skilled in the art can realize that the disclosed technology by no means is limited to the embodiments described above. On the contrary, many modifications and variations are possible within the scope of the appended claims. For example, while in the illustrated examples, the PMOS devices are provided in the bottom tier and the NMOS devices are provided in the top tier, it is also possible to provide the NMOS devices in the bottom tier and the PMOS devices in the top tier. This may be done without any change to the inverter cross-coupling, but only some corresponding permutation of the power rails and routing tracks, for instance the configuration of the power rails VDD, VSS such that there are two instances of the pull-down power rail VSS and one instance of the pull-up power rail VDD. Additionally, while in the illustrated examples the CFET devices are of a configuration which may be obtained using e.g. the sequential CFET process. It is envisaged that analogous bit cell layouts may be achieved using a monolithic CFET process, supplemented with additional process steps forming split gates between the bottom and top pass gates.

What is claimed is:

1. A static random access memory (SRAM) device comprising:
a plurality of bit cells, each bit cell comprising a first half-cell and a second half-cell, each half-cell comprising:
a first complementary field-effect transistor (CFET) device; and
a second CFET device, each of the first and second CFET devices comprising a bottom device and a top device stacked on top of the bottom device,
wherein the first CFET device comprises a common gate shared by the bottom device and the top device and is configured as an inverter cross-coupled to the inverter of other of the first and second half-cells,
wherein the bottom device of the second CFET device is configured as a first pass-gate for a first port of the half-cell, the bottom device comprising a bottom gate coupled to a first word line, and
wherein the top device of the second CFET device is configured as a second pass-gate for a second port of the half-cell, the top device comprising a top gate which is separate from the bottom gate and is coupled to a second word line.

2. The SRAM device of claim 1,
wherein the common gate of the first CFET device of the first half-cell and the bottom and top gates of the second CFET device of the second half-cell are arranged along a first gate track, wherein the common gate of the first CFET device of the second half-cell and the bottom and top gates of the second CFET device of the first half-cell are arranged along a second gate track, the first and second gate tracks being parallel to a cell height dimension of the bit cell, and
wherein each CFET device comprises a first source or drain (S/D) region and a second S/D region, wherein the first and second S/D regions of the CFET devices of the first half-cell are arranged along a first active track, wherein the first and second S/D regions of the CFET devices of the second half-cell are arranged along a second active track, the first and second active tracks being parallel to a cell width dimension of the bit cell and transverse to the cell height dimension.

3. The SRAM device of claim 2,
wherein the first half-cell comprises a first common S/D contact arranged between and shared by the first and second CFET devices of the first half-cell, wherein the second half-cell comprises a second common S/D contact arranged between and shared by the first and second CFET devices of the second half-cell,
wherein the common S/D contact of the first and second half-cell each comprise a contact extension protruding towards the common S/D contact of the other half-cell,
wherein the common gates of the first CFET devices of the first and second half-cells define first and second common gates, respectively, wherein the first and second common gates each comprise a gate extension protruding towards the second CFET device of the other half-cell, and
wherein the bit cell further comprises:
a first local cross-coupling interconnect extending between and interconnecting respective tip portions of the gate extension of the first common gate and the contact extension of the second common S/D contact, and
a second local cross-coupling interconnect extending between and interconnecting respective tip portions of the gate extension of the second common gate and the contact extension of the first common S/D contact.

4. The SRAM device of claim 3, wherein the tip portion of the gate extension of the first common gate is separated from a tip portion of the bottom and top gates of the second CFET device of the second half-cell by a first gate cut region, and wherein the tip portion of the gate extension of the second common gate is separated from a tip portion of the bottom and top gates of the second CFET device of the first half-cell by a second gate cut region.

5. The SRAM device of claim 3, wherein each of the first and second local cross-coupling interconnect is configured as a first and second metal strap, respectively, extending along the cell width dimension to bridge a distance between the respective tip portions.

6. The SRAM device of claim 5, wherein the first and second metal straps are arranged on top of the respective tip portions.

7. The SRAM device of claim 5,
wherein the bottom devices are arranged in a bottom device tier of the bit cell, wherein the top device are arranged in a top device tier of the bit cell,
wherein the gate extension of the first common gate and the contact extension of the second common S/D contact are arranged in the bottom device tier but not the top device tier, and
wherein the gate extension of the second common gate and the contact extension of the first common S/D contact are arranged in the top device tier but not the bottom device tier.

8. The SRAM device of claim 7, wherein the contact extensions protrude at least a midline of the bit cell.

9. The SRAM device of claim 7, wherein each bottom device is a nanosheet-FET device, and wherein each top device is a Fin Field-effect Transistor device comprising a channel structure with a width dimension smaller than a width dimension of a channel structure of each nanosheet-FET device.

10. The SRAM device of claim 5,
wherein the bottom devices are arranged in a bottom device tier of the bit cell and the top devices are arranged in a top device tier of the bit cell, and
wherein the gate extensions of the first and second common gates and the contact extensions of the first and second common S/D contacts are arranged in at least the top device tier.

11. The SRAM device of claim 1,
wherein the first and second pass-gates of the first half-cell are coupled to a first and second bit line, respectively,
wherein the first and second pass-gates of the second half-cell are coupled to a first and second complementary bit line, and
wherein the inverters of the first and second half-cells are coupled to a first power rail and second power rail, one providing a pull-up voltage and the other providing a pull-down voltage.

12. The SRAM device of claim 11,
wherein the inverter of the first half-cell is coupled to a first instance of the first power rail, wherein the inverter of the second half-cell is coupled to a second instance of the first power rail, wherein the first and second instances of the first power rail are configured as a respective buried power rail extending along a bottom and top edge of the respective bit cell, and
wherein the inverters of the first and second half-cells are coupled to an instance of the second power rail, wherein the instance of the second power rail is configured as a buried power rail extending along a midline of the respective bit cell or as a metal line arranged in a routing track of an interconnect level above the bit cell.

13. The SRAM device of claim 12, wherein the instance of the second power rail is configured as a metal line arranged in a routing track of an interconnect level above the bit cell, and wherein the first bit line and the first complementary bit line are configured as buried signal lines, arranged between the first and second instances of the first power rail.

14. The SRAM device of claim 13, wherein the routing track is a mid track of a set of routing tracks of the interconnect level and associated with the bit cell, the set of routing tracks extending along a cell width dimension and further comprising:
first and second edge tracks overlapping a top and bottom edge of the bit cell, respectively,
first and second off-center tracks arranged on opposite sides of the mid track,
a third off-center track arranged between the first off-center track and the first edge track, and
a fourth off-center track arranged between the second off-center track and the second edge track,
wherein first and second instances of the first word line are arranged in the first and second edge tracks, respectively,
wherein first and second instances of the second word line are arranged in the third and fourth off-center tracks, respectively, and
wherein the second bit line and the second complementary bit line are arranged in the first and second off-center tracks, respectively.

15. The SRAM device of claim 1, wherein the bottom device of each CFET is a p-channel metal-oxide Semiconductor device, and wherein the top device of each CFET is an n-channel metal-oxide Semiconductor device.

16. The SRAM device of claim 1, wherein the bottom device of each CFET is an n-channel Metal-oxide Semiconductor device, and wherein the top device of each CFET is a p-channel Metal-oxide Semiconductor device.
